(19) United States
(12) Patent Application Publication
(10) Pub. No.: US 2003/0012005 A1
(43) Pub. Date: Jan. 16, 2003

(54) Electronic circuit device

(76) Inventors: Yoshinori Ito, Tokyo (JP); Kunio Oshimo, Kanagawa (JP); Mikito Imai, Aichi (JP); Hiroshi Ozaki, Saitama (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 10/204,257

(22) PCT Filed: Dec. 18, 2001
(86) PCT No.: PCT/JP01/11089

(30) Foreign Application Priority Data
Dec. 19, 2000 (JP) 2000-385305

(51) Int. Cl. H05K 5/00; H05K 5/04

(52) U.S. Cl. 361/752; 361/757

(57) ABSTRACT

According to an electronic circuit device, when a circuit board having electrical parts mounted thereon is sealed with resin, the heat and pressure of the resin is prevented from acting on the electrical parts thus mounted. A circuit board (10) having electrical parts (11) and an IC (12) mounted thereon is accommodated in a sleeve formed of a thermal-shrinkage film (16), and subjected to thermal shrinkage to intermediate-package the circuit board. Thereafter, the overall body thereof is molded with a resin (17) and the circuit board (10) is sealed.

### TECHNICAL FIELD

The present invention relates to an electronic circuit device, and particularly to an electronic circuit device that is designed so that electrical parts are mounted on a circuit board and sealed with resin.

### BACKGROUND ART

An electronic circuit device is constructed by etching copper foil joined onto the surface of a substrate composed of insulating material to form a wiring pattern, mounting electrical parts on the circuit board having the wiring pattern thus formed and mutually connecting the electrodes of the electrical parts to one another by the wiring pattern to form a desired circuit. Such an electronic circuit device is mounted as it is and used in a cabinet.

There is a case where such a circuit board having electrical parts mounted thereon is not used while the electrical parts are exposed, but used while such an electronic circuit device is sealed with resin. The resin-sealing enhances the withstanding voltage, prevents oxidation and further excludes the effects of water droplets and steam. Accordingly, the resin-sealing may be required in accordance with an atmospheric condition under which the electronic circuit device is used. Further, such resin-sealing contributes to miniaturization of the electronic circuit device.

As a miniaturizing manner in the electronic equipment manufacturing as described above, it is known that a circuit board having electronic parts mounted thereon is sealed by insert-molding using resin or the like. When such resin-sealing is carried out, the electronic circuit device is disposed in the cavity of a die and melted resin is injected into the cavity. Accordingly, the electrical parts on the circuit board are brought into direct contact with the melted resin, and thus there is such a problem that the electrical parts cannot withstand the temperature of the molten resin or solder with which the electrodes of the electrical parts are connected to a connecting land of the circuit board is melted by the heat of the melted resin, result in movement of the parts.

Further, in such a molding process, the pressure of the resin injected into the cavity of the die may reach several hundreds Kg per square centimeter, so that there occurs such a situation the electrical parts themselves cannot withstand the pressure and thus these parts cannot exhibit their original characteristics.

The present invention has been implemented in view of the foregoing problem, and has an object to provide an electronic circuit device with which electrical parts on a circuit board can be avoided from adverse effects of the heat of melted resin or the pressure of the molten resin particularly in a molding process for sealing, thereby overcoming the problem in quality of the electrical circuit device sealed with resin.

### DISCLOSURE OF THE INVENTION

The main invention of this application relates to an electronic circuit device constructed by mounting electrical parts on a circuit board and sealing the electrical parts with resin, characterized in that the circuit board having the electrical parts mounted thereon is sealed with resin under the state that it is packaged by an intermediate packaging member.

Here, it is preferable that the intermediate packaging member comprises a thermal-shrinkage film or a case in which the circuit board is mounted. The intermediate packaging member can be sealed with resin under the state that a part of the circuit board is packaged by the intermediate packaging member, thereby directly sealing some of parts with resin. Further, an opening is formed in the intermediate packaging member, and electrical parts mounted at the site corresponding to the opening may be directly sealed with resin without the intermediate packaging member intervening therebetween.

Polyethylene or bridged polyethylene is preferably used for the thermal-shrinkage film used in this embodiment. Various kinds of thermoplastic resin or thermosetting resin such as polystyrene, polycarbonate, and liquid epoxy resin are broadly used as the resin to be injected.

According to a preferred embodiment of the invention contained in this application, when electrical parts used for electronic equipment are sealed with resin or the like by insert-molding, the electrical parts or a circuit board having the electrical parts mounted thereon is covered by an intermediate packaging member such as a thermal-shrinkage tube, and the molding based on the insert-molding of resin is conducted after thermal shrinkage, whereby the circuit board having the electrical parts mounted thereon is sealed with the resin.

According to this embodiment, even when the upper limit temperature of the heat resistance of the electrical parts is lower than the melting temperature of resin to be injected, the electrical parts are prevented from coming into direct contact with the resin by the intermediate packaging member, so that the range of usable electrical parts can be broadened. Even when the melting temperature of solder used to connect the electrical parts is lower than the melting temperature of the sealing resin, solder having a low melting point can be selected because the direct contact between the electrical parts and the resin can be prevented by the intermediate packaging member, so that the selectivity of the solder can be broadened.

When resin is injected in the resin sealing process as described above, pressure is applied. However, the molding is carried out under the state that the electronic circuit board having the electrical parts mounted thereon is packaged by the intermediate packaging member, and thus the applied pressure can be more greatly reduced as compared with the case where the pressure of resin is directly applied to the electrical parts. Accordingly, parts having low pressure resistance can be used. Further, the accidence that electrical parts are broken due to the pressure of resin when the resin is injected can be suppressed, or the probability that the electrical parts do not exhibit their original functions due to the pressure of resin can be reduced.

When the resin-sealing is carried out, space occurs between the electrical parts and the intermediate packaging member, so that the resin amount used can be lowered and the cost can be reduced. Further, since space exists between the electrical parts and the intermediate packaging member, the amount of the resin material used can be lowered, and the weight of the electronic circuit device can be reduced.

The following effects can be achieved by selecting the range of the intermediate packaging member to be covered on the electronic circuit device. That is, with respect to parts having high resistance to temperature and pressure such as a semiconductor memory, these parts are disposed on an area which is not covered by the intermediate packaging member so that the electrical parts in the area can be directly sealed by the resin. Even if it is tried to read out or hack the content of the semiconductor memory in such a structure, it is difficult to perform such an action. Accordingly, this structure is effective from the viewpoint of security.

According to the structure that the circuit board having the electrical parts mounted thereon is molded and sealed with resin while they are packaged by the intermediate packaging member, the close contact between the resin and the electrical parts can be prevented by the intermediate packaging member, and the bending tenacity of the overall electronic circuit device can be enhanced. The enhancement of the bending tenacity contributes to reliability of the electronic circuit device.

### BRIEF DESCRIPTION OF THE DRAWINGS

FIGS. 1A to 1D are perspective views of the main part which show the sealing operation of resin into an electronic circuit device according to a first embodiment of the present invention.

FIGS. 2A to 2D are longitudinally-sectional views showing the main part.

FIGS. 3A to 3C are longitudinally-sectional views of the main part which show the resin sealing operation according to a second embodiment.

FIGS. 4A to 4C are longitudinally-sectional views of the main part which show the resin sealing operation according to a third embodiment.

FIGS. 5A to 5C are perspective views and longitudinally-sectional views showing the resin sealing operation according to a fourth embodiment.

### BEST MODES FOR CARRYING OUT THE INVENTION

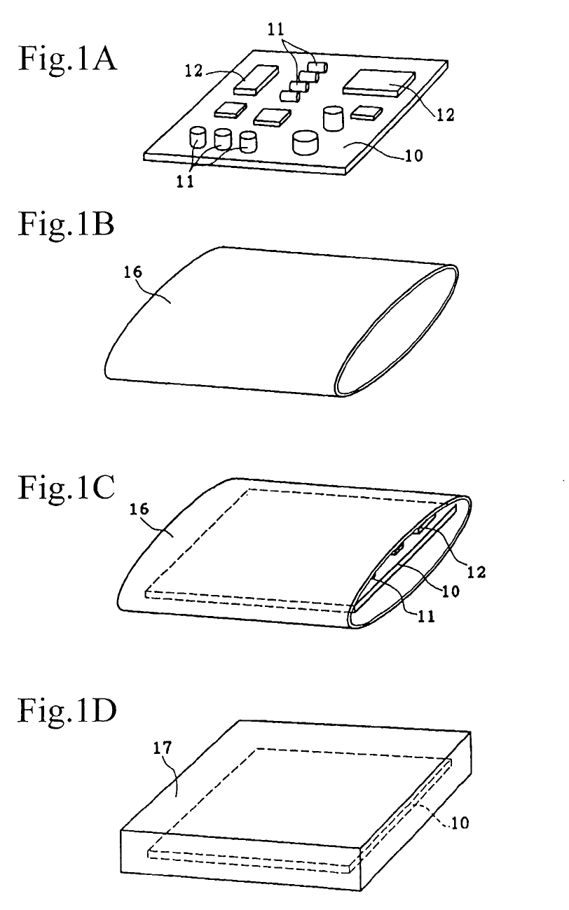

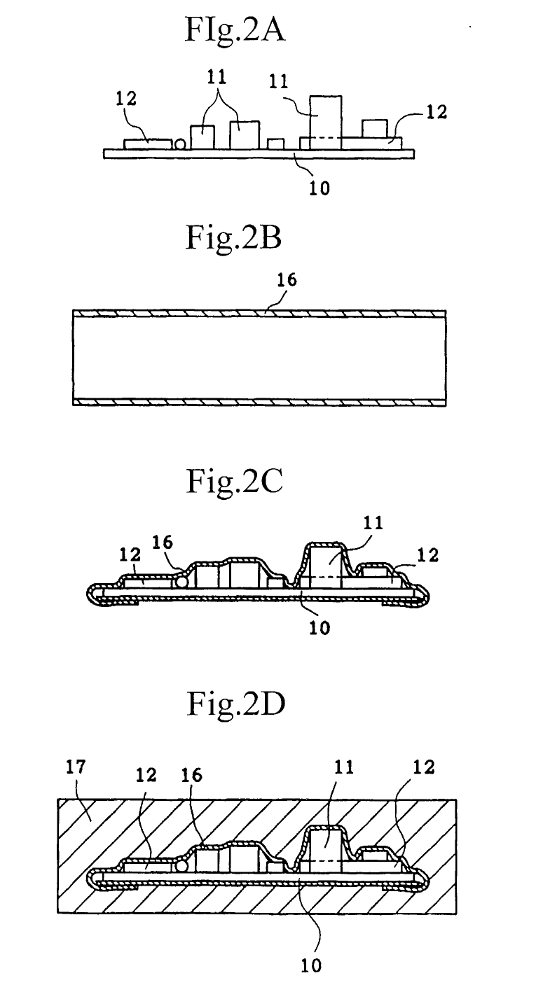

FIGS. 1A to 1D and FIGS. 2A to 2D show the resin sealing process of an electronic circuit device according to a first embodiment of the present invention step by step. As shown in FIGS. 1A and 2A, a circuit board 10 formed of insulating material such as epoxy resin, or ceramics is used. A wiring pattern achieved by etching copper foil joined is formed on the circuit board 10 as described above, and the electrodes of electrical parts 11 mounted on the wiring pattern are connected to one another by the wiring pattern to form a prescribed electronic circuit. As occasion demands, an IC 12 is mounted on the circuit board 10 together with the electrical parts 11.

In the resin sealing process of the circuit board 10 as described above, before the resin sealing process, a thermal-shrinkage film 16 such as polyethylene film is used and the circuit board 10 is packaged by the thermal-shrinkage film 16. The thermal-shrinkage film 16 is designed in a cylindrical shape as shown in FIGS. 1B and 2B, and the size thereof is set to such a value that the circuit board 10 can be accommodated with a sufficient margin.

As shown in FIGS. 1C and 2C, the circuit board 10 having the electrical parts 11 and the IC 12 mounted thereon is accommodated in a sleeve formed of such thermal-shrinkage film 16, and shrink packaging based on thermal shrinkage is conducted to perform intermediate packaging. The circuit board 10 that has been intermediate-packaged by the thermal-shrinkage film 16 as described above is disposed in the cavity of a die for molding, and under this state, a sealing resin 17 such as polystyrene, polycarbonate, or liquid epoxy resin is injected into the cavity to mold the circuit board 10. FIGS. 1D and 2D show a sealing state achieved by conducting such molding and sealing with the sealing resin 17.

As described above, according to this embodiment, the circuit board 10 having the parts 11, 12 mounted thereon is accommodated in the tube formed of the thermal-shrinkage film 16 having heat resistance, and the tube is thermally contracted and intermediate-packaged. In this case, it is preferable that the above process is carried out after sites to be covered by the thermal-shrinkage tube 16 are determined, and the thermal-shrinkage tube is cut by such length that these sites can be covered by the thermal-shrinkage tube, and positioned, if necessary.

The circuit board 10 intermediate-packaged by the thermal-shrinkage film 16 is put in the cavity of the die and resin is injected to thereby seal the circuit board 10 with the sealing resin 17.

According to the structure as described above, even when the upper-limit temperature of the heat resistance of the electrical parts 11, 12 is lower than the melting temperature of the resin 17, the thermal-shrinkage tube 16 acts as a cushion to prevent the direct contact between the electrical parts 11, 12 and the melted resin, so that the using range of the electrical parts 11, 12 can be expanded. Further, even when the melting temperature of solder used to connect the electrodes of the electrical parts 11, 12 to one another is lower than the melting temperature of the sealing resin 17, the direct contact between the resin and the electrical parts 11, 12 can be prevented by the thermal-shrinkage tube 16, so that the probability that solder having low melting point is selected and used can be increased.

Further, even when there is a risk that the electrical parts 11, 12 are broken by the injection pressure of the resin 17 or there is a probability that the parts 11, 12 lose their original functions due the pressure of resin, the parts 11, 12 are prevented from coming into direct contact with the resin by the thermal-shrinkage tube 16. Therefore, as compared with the direct pressure applied to the electrical parts 11, 12, the pressure is reduced and thus the selection range of the parts 11, 12 can be enlarged.

Further, slight space exists between the parts 11, 12 on the circuit board 10 and the thermal-shrinkage tube 16 as shown in FIG. 2D. Accordingly, the amount of material used is reduced by such space, and the weight is reduced, so that it contributes to reduction in weight. In addition, since the close contact between the sealing resin 17 and the electrical parts 11, 12 is prevented as described above, the overall bending tenacity of the electronic circuit device can be enhanced.

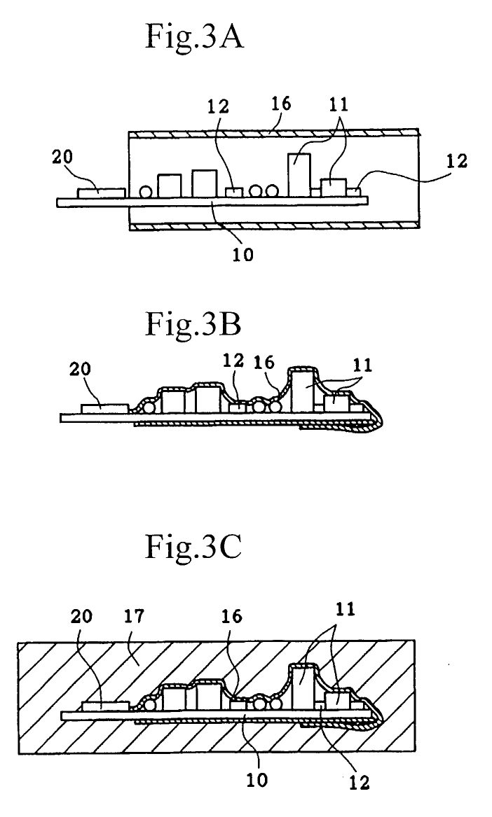

Next, another embodiment will be described with reference to FIGS. 3A to 3C. According to this embodiment, the whole of the circuit board 10 having the electrical parts 11, 12 mounted thereon is not packaged by the thermal-shrinkage film 16, but it is packaged by the thermal-shrinkage film 16 while a part of the circuit board 10 is exposed, if necessary. That is, as shown in FIGS. 3A and 3B, only a portion which is the left edge portion of the circuit board 10 and, for example, on which a semiconductor memory 20 is mounted is not shrink-packaged by the thermal-shrinkage film 16, and is left exposed.

Under this state, the circuit board 10 having the electrical parts 11, 12, 20 mounted thereon is disposed in the die and subjected to the resin molding, whereby it is covered by the sealing resin 17. In this case, at an inside portion of the thermal-shrinkage film 16, the electrical parts 11, 12 are not brought into contact with the sealing resin 17. At a portion which is not covered by the thermal-shrinkage film 16, the semiconductor memory 20, etc. on the circuit board 10 are directly sealed by the resin.

The following merit can be achieved by selecting areas to be covered by the thermal-shrinkage film 16 as described above. That is, with respect to an electrical part having high resistance to temperature and pressure, such as a semiconductor memory 20, it is disposed in an area which is not covered by the thermal-shrinkage film 16. The electrical parts 20 in such areas are integrated with one another by the sealing resin 17. Accordingly, even if it is tried to read out or hack the content of the semiconductor memory 20, it cannot be easily performed, and thus an effect can be achieved in security.

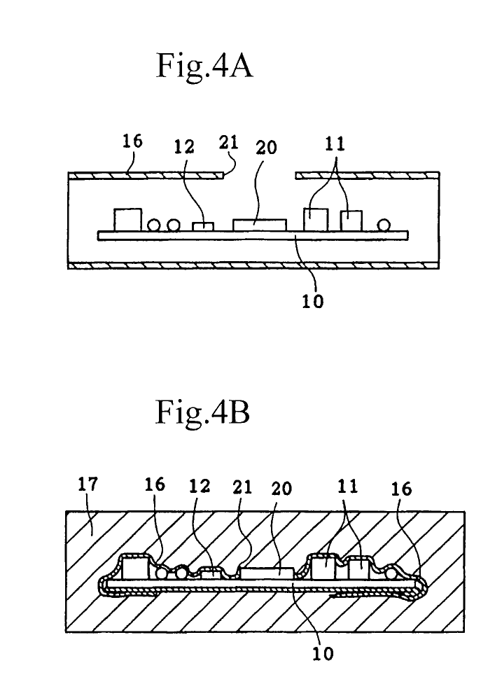

Next, another embodiment will be described with reference to FIGS. 4A to 4B. According to this embodiment, an opening 21 is formed in a part of the sleeve formed of the thermal-shrinkage film 16, and the opening 21 is confronted to the semiconductor memory 20. Accordingly, if the thermal shrinkage is conducted under such a state, the other electrical parts 11, 12 on the circuit board 10 are intermediate-packaged by the thermal-shrinkage film 16, however, the semiconductor memory 20 is exposed through the opening 21. Accordingly, if the resin molding is carried out under this state, the semiconductor memory 20 is directly sealed by the resin, and the other electrical parts 11, 12 are indirectly sealed by the sealing resin 17 while they are intermediate-packaged by the thermal-shrinkage film 16.

According to this structure, particularly even in such a case that a semiconductor memory 20 which is required to be directly sealed by resin is not located at the edge portion of the circuit board 10, but located at an intermediate position, only the semiconductor memory 20 can be selectively directly sealed with resin. Accordingly, the content of the semiconductor memory 20 can be protected.

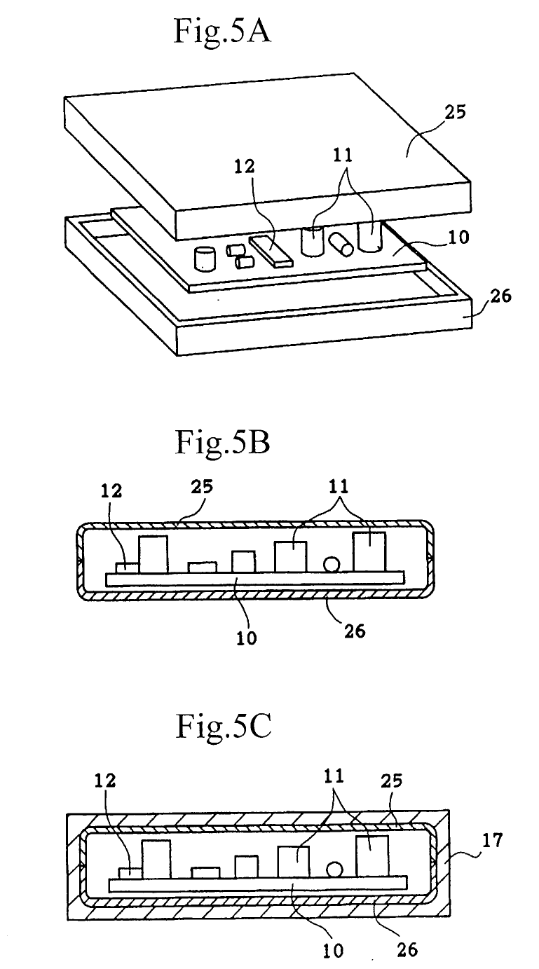

Next, another embodiment will be described with reference to FIGS. 5A to 5C. According to this embodiment, a pair of upper and lower cases 25, 26 are used in place of use of the sleeve of the thermal-shrinkage film 16, these cases 25, 26 are used as intermediate members to package the circuit board 10, and the circuit board 10 is sealed from the outside thereof with the sealing resin 17.

The intermediate packaging member for packaging the circuit board 10 having the electrical parts 11, 12 mounted thereon is not limited to the thermal-shrinkage film 16, but various kinds of packaging means may be used. When the pair of upper and lower cases 25, 26 are used, for example, a resin case or metal case is preferably used. The circuit board 10 is temporarily cased by the cases 25, 26 and then subjected to insert-molding.

Even in the case of such a structure, the temperature and the pressure in the molding process of the sealing resin 17 hardly act on the electrical parts 11, 12 on the circuit board 10, and the effect of the temperature and pressure in the resin molding process can be reduced. Further, lots of space can be secured by the intermediate cases 25, 26, so that the use amount of the sealing resin 17 can be reduced and the weight of the overall device can be reduced.

According to the main invention of this application, in the electronic circuit device constructed by mounting the electrical parts on the circuit board and sealing them with resin, the circuit board having the electrical parts mounted thereon is sealed with resin while packaged by the intermediate packaging member.

Accordingly, according to this construction, the heat and the pressure are prevented from directly acting on the electrical parts on the circuit board by the intermediate packaging member, and the using range of the electrical parts and solder for connection can be enlarged. The breaking of the electrical parts and the lose of the functions due to the pressure in the resin injection process can be prevented. The using amount of the resin material can be reduced by the space occurring between the intermediate packaging member and the electrical parts and the weight can be reduced, thereby contributing to weight saving. Further, there is an advantage that the bending tenacity of the overall electronic circuit device can be enhanced.

1. An electronic circuit device for mounting electrical parts on a circuit board and sealing the electrical parts with resin, characterized in that the circuit board having the electrical parts mounted thereon is sealed with resin under the state that the circuit board is packaged by an intermediate packaging member.

2. The electronic circuit device as claimed in claim 1, wherein said intermediate packaging member is formed of thermal-shrinkage film.

3. The electronic circuit device as claimed in claim 1, wherein said intermediate packaging member is a case in which the circuit board is accommodated.

4. The electronic circuit device as claimed in claim 1, wherein said intermediate packaging member is sealed with the resin under the state that a part of said circuit board is packaged by said intermediate packaging member.

5. The electronic circuit device as claimed in claim 1, wherein an opening is formed in said intermediate packaging member, and an electrical part mounted at the site corresponding to said opening is directly sealed with the resin without said intermediate packaging member intervening between the electrical part and the resin.
